(19) United States
(12) Patent Application Publication
(10) Pub. No.: US 2026/0293620 A1
(43) Pub. Date: Sep. 24, 2026

(54) METHOD FOR MANUFACTURING EPITAXIAL WAFER

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Shinya SATO, Nonoichi Ishikawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/312,421

(22) Filed: Aug. 28, 2025

(30) Foreign Application Priority Data
Mar. 21, 2025 (JP) 2025-046598

(51) Int. Cl. H01L 21/02

(52) U.S. Cl. CPC H10P 90/128; H10P 90/123; H10P 90/124; H10P 90/18

(57) ABSTRACT

A method for manufacturing an epitaxial wafer according to an embodiment includes: covering a semiconductor wafer with a first film that suppresses epitaxial growth; obliquely polishing a bevel portion on a front surface side of the semiconductor wafer, thereby removing the first film on the bevel portion on the front surface side to form an outer peripheral slope on which a first layer of the semiconductor wafer is exposed; polishing a flat portion surrounded by the outer peripheral slope on the front surface side of the semiconductor wafer, thereby removing the first film on the flat portion to form a first surface on which the first layer of the semiconductor wafer is exposed; and forming a second layer on the first surface of the semiconductor wafer.

### CROSS-REFERENCE TO RELATED APPLICATION

This application is based upon and claims the benefit of priority from prior Japanese Patent Application No. 2025-046598, filed on Mar. 21, 2025; the entire contents of which are incorporated herein by reference.

### FIELD

Embodiments described herein relate generally to a method for manufacturing an epitaxial wafer.

### BACKGROUND

A semiconductor wafer (hereinafter also referred to as an “epitaxial wafer”) on which an epitaxial layer is formed is used to manufacture a semiconductor device. In order to manufacture a power semiconductor device of high voltage resistance, an epitaxial wafer is sometimes used that has a relatively thick (e.g., 50 μm or more) epitaxial growth layer.

In an epitaxial wafer manufacturing process, when epitaxial growth is performed while a single crystal on the surface of a semiconductor wafer and a bevel portion (chamfered outer periphery) is exposed, the crystal planes (facets) such as the {110} plane may be formed at the front end of the bevel portion, causing the bevel portion to have a pointed shape. The pointed shape of the bevel portion becomes more pronounced as the epitaxial layer is formed thicker.

### BRIEF DESCRIPTION OF THE DRAWINGS

FIG. 1 is a diagram showing a flowchart for describing a method for manufacturing an epitaxial wafer according to a first embodiment;

FIG. 2 is a diagram schematically showing a manufacturing process for an epitaxial wafer according to the first embodiment;

FIG. 3A is a schematic cross sectional view of an epitaxial wafer, produced by a manufacturing method according to a comparative example, on which a step P occurs;

FIG. 3B is a schematic cross sectional view of an epitaxial wafer, produced by a manufacturing method according to the comparative example, on which a stacking fault occurs;

FIG. 4A is a schematic cross sectional view of an epitaxial wafer produced by the manufacturing method according to the first embodiment;

FIG. 4B is a schematic cross sectional view of an epitaxial wafer, produced by the manufacturing method according to the first embodiment, on which a stacking fault occurs;

FIG. 5 is a diagram showing angles that outer peripheral slopes make with a horizontal plane and the corresponding Miller indices of outer peripheral slopes;

FIG. 6 is a diagram showing a flowchart for describing a method for manufacturing an epitaxial wafer according to a second embodiment; and

FIG. 7 is a diagram schematically showing a manufacturing process for an epitaxial wafer according to the second embodiment.

### DETAILED DESCRIPTION

A method for manufacturing an epitaxial wafer according to an embodiment includes: covering a semiconductor wafer with a first film that suppresses epitaxial growth; obliquely polishing a bevel portion on a front surface side of the semiconductor wafer, thereby removing the first film on the bevel portion on the front surface side to form an outer peripheral slope on which a first layer of the semiconductor wafer is exposed; polishing a flat portion surrounded by the outer peripheral slope on the front surface side of the semiconductor wafer, thereby removing the first film on the flat portion to form a first surface on which the first layer of the semiconductor wafer is exposed; and forming a second layer on the first surface of the semiconductor wafer.

Embodiments according to the present invention are described below with reference to the drawings. The embodiments do not limit the present invention. The drawings are schematic or conceptual, and the ratio of each part is not necessarily the same as the actual one. In the specification and drawings, elements similar to those described above with respect to the previously mentioned drawings are given the same reference numerals and characters, and detailed explanation is omitted as appropriate.

### First Embodiment

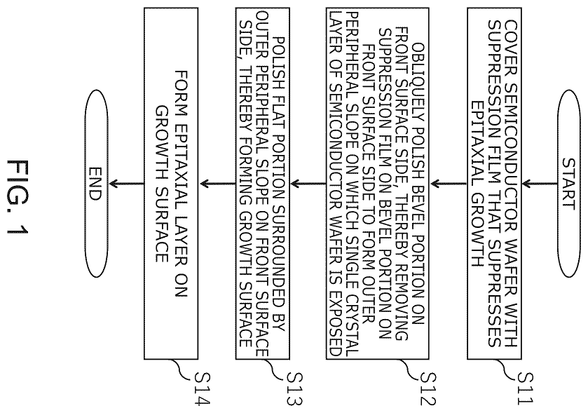

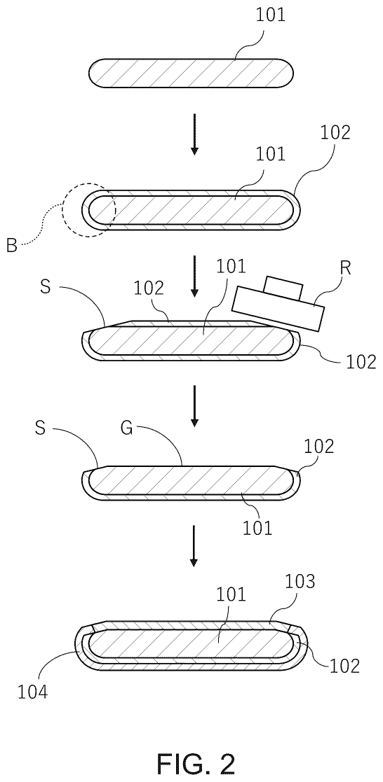

With reference to FIGS. 1 and 2, a method for manufacturing an epitaxial wafer according to the first embodiment is described. FIG. 1 is a flowchart of the method for manufacturing the epitaxial wafer according to this embodiment. FIG. 2 is a schematic view corresponding to FIG. 1, showing the manufacturing process of the epitaxial wafer according to this embodiment.

Step S11: A semiconductor wafer 101 is prepared. The semiconductor wafer 101 is, for example, a silicon wafer. The semiconductor wafer 101 is covered with a suppression film 102 that suppresses epitaxial growth. The suppression film 102 referred to here is an example of a first film in the claims. Specifically, a polysilicon film (polycrystalline silicon film) is formed on the entire surface of the semiconductor wafer 101 using chemical vapor deposition (CVD). The deposition method is not limited to CVD, and the suppression film 102 may be deposited by physical vapor deposition (PVD) such as sputtering.

The purpose of step S11 is to cover the semiconductor wafer with a suppression film that suppresses epitaxial growth. For this reason, the suppression film 102 to be used is not limited to a polysilicon film, and may be any film having the properties and thickness of a suppression film for epitaxial growth. For example, the suppression film 102 may be a polycrystalline film or an amorphous film, other than the polysilicon film.

Step S12: A bevel portion B on the front surface side of the semiconductor wafer 101 is polished obliquely to remove the suppression film 102 on the bevel portion B on the front surface side, thereby forming an outer peripheral slope S on which the single crystal layer of the semiconductor wafer 101 is exposed. The single crystal layer referred to here is an example of a first layer in the claims. Specifically, as shown in FIG. 2, a grindstone R is applied to the bevel portion B on the front surface side, and the semiconductor wafer 101 is rotated, thereby grinding the bevel portion B obliquely with respect to the horizontal plane.

The outer peripheral slope S formed in this step is formed in a ring shape in a plan view of the semiconductor wafer 101. The magnitude of the facet angle θ that the outer peripheral slope S makes with the horizontal plane is described below.

The method for forming the outer peripheral slope S is not limited to the method using the grindstone R. For example, a polishing tape may be used, a chemical mechanical polishing (CMP) device may be used, or chemical or physical etching may be used.

Step S13: The flat portion is polished that is surrounded by the outer peripheral slope S on the front surface side of the semiconductor wafer 101, thereby removing the suppression film 102 on the flat portion to form a growth surface G on which the single crystal layer is exposed. The growth surface G referred to here is an example of a first surface in the claims. Specifically, the flat portion is polished using a CMP device to form the growth surface G.

The polishing method is not limited to the method using a CMP device, and may use polishing methods or flattening techniques using a grindstone, abrasive cloth, etching, or the like.

Step S14: An epitaxial layer 103 is formed on the growth surface G of the semiconductor wafer 101. The thickness of the epitaxial layer 103 is, for example, in the range of 50 μm to 200 μm inclusive. The epitaxial layer 103 referred to here is an example of a second layer in the claims. The epitaxial layer 103 is, for example, a silicon epitaxial layer. In this step, a growth region 104 is formed by epitaxial growth processing on the suppression film 102 except for that on the front surface side. The growth region 104 is made of, for example, polysilicon.

Specifically, the epitaxial growth processing in step S14 is performed by a CVD method. Note that the epitaxial growth layer may be formed by other methods such as Liquid Phase Epitaxy (LPE) and Molecular Beam Epitaxy (MBE).

Epitaxial wafers produced through the above steps are used to manufacture semiconductor devices such as diodes, Metal-Oxide-Semiconductor Field-Effect Transistors (MOSFETs), and Insulated Gate Bipolar Transistors (IGBTs).

### Actions and Effects

Before description of the effects of the method for manufacturing the epitaxial wafer according to this embodiment, a manufacturing method for an epitaxial wafer (comparative example) is described in which step S12 is not performed.

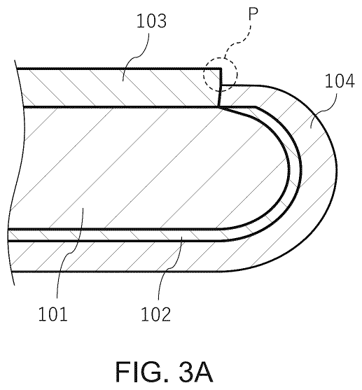

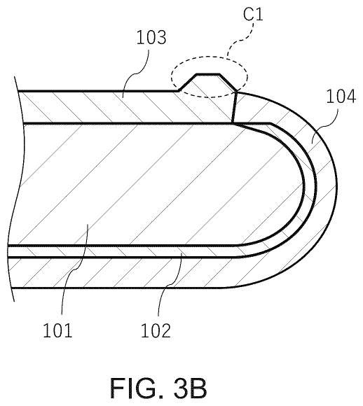

FIG. 3A is a schematic cross sectional view of an epitaxial wafer produced by a manufacturing method according to the comparative example in which step S12 is not performed. As shown in the figure, a vertical step P occurs between the epitaxial layer 103 and a growth region 104 formed on the suppression film 102. In other words, a step P occurs on the {100} plane of the epitaxial layer 103.

FIG. 3B is a schematic cross sectional view of an epitaxial wafer produced by a manufacturing method according to the comparative example in which step S12 is not performed. As shown in the figure, a stacking fault C1 occurs between an epitaxial layer 103 and a growth region 104 formed on the suppression film 102. The stacking fault referred to here is also called a pyramid, and refers to a crystal defect that protrudes above the epitaxial plane.

When the epitaxial wafer is contained in a wafer case or when the epitaxial wafer is fixed (chucked) in various processes such as deposition, etching, and dicing, the step P may get caught in the case or the like, causing occurrence of chipping. In addition, if the stacking fault C1 protrudes above the upper surface (device surface) of the epitaxial layer 103 as shown in FIG. 3B, for example, when the epitaxial wafer is contained in a cassette case, the stacking fault C1 may get caught in the case, causing chipping. In addition, when the epitaxial wafer (epitaxial layer) and the glass substrate are bonded with an adhesive in the backside process, the amount of protrusion of the stacking fault C1 is larger than the thickness of the adhesive, which may cause occurrence of chipping.

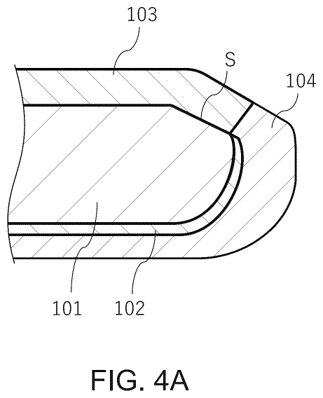

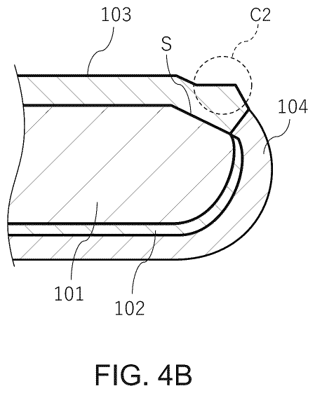

In contrast, the epitaxial wafer produced by a manufacturing method according to this embodiment does not have the above problem. FIG. 4A is a schematic cross sectional view of an epitaxial wafer produced by the manufacturing method according to this embodiment. As shown in the figure, when the outer peripheral slope S is formed, the epitaxial layer 103 is also formed on the outer peripheral slope S and inclines downward at a gentle angle toward the edge of the semiconductor wafer. In other words, a high-index crystal plane such as a {311} plane is formed on the outer peripheral slope S. This can suppress the step P shown in FIG. 3A from occurring.

FIG. 4B is a schematic cross sectional view of an epitaxial wafer produced by the manufacturing method according to this embodiment. As shown in the figure, forming an outer peripheral slope S causes the epitaxial layer 103 to incline downward toward the edge. This can suppress the stacking fault C2 from protruding above the upper surface (device surface) of the epitaxial layer 103 if a stacking fault C2 occurs.

As described with reference to FIGS. 4A and 4B, in this embodiment, forming the outer peripheral slope S makes it possible to manufacture an epitaxial wafer capable of suppressing the occurrence of a steps P and stacking faults C1 and improving the yield of semiconductor devices.

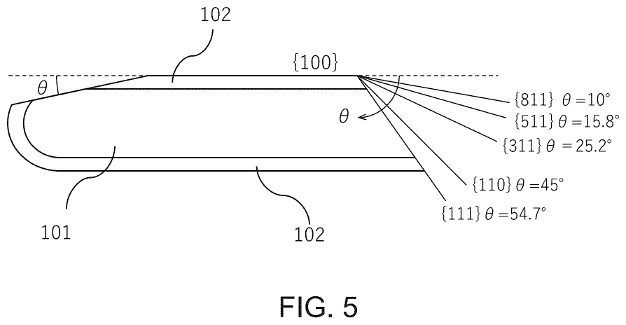

Next, the magnitude of the facet angle θ is described that the outer peripheral slope S of the semiconductor wafer makes with the horizontal plane. FIG. 5 is a diagram showing the facet angles θ in {100} or {110} cross-section that the outer peripheral slopes S makes with the horizontal plane and the corresponding Miller indices of the outer peripheral slopes S. It is desirable that the facet angle θ be large enough to avoid defects due to the step P and stacking fault C1, and for example, it is desirable that the facet angle θ be θ ≥10°. Note that θ=10° corresponds to the plane.

On the other hand, as for the upper limit value of the facet angle θ, too large a value of θ increases the risk of occurrence of the crown (an elevated portion of the epitaxial layer at the peripheral portion) protruding above the device surface. For this reason, the upper limit value of the facet angle θ is set to, for example, 45°. Note that θ=45° corresponds to the {110} plane.

In this way, the facet angle θ is set, for example, within the range of 10° to 45°. In order to further reduce the risk of occurrence of steps in the epitaxial layer and crowns, it is more desirable to set the facet angle θ within the range of 10° to 25.2°. Note that θ=25.2° corresponds to the plane. These numerical range may be optionally narrowed to exclude a part (or to exclude a point within the range), and the similar actions and effects are achieved in the range after the exclusion.

Note that when semiconductor devices are manufactured through a manufacturing process in which the occurrence of crowns is not a major problem, the upper limit value of the facet angle θ may be set to 45° or more (for example, 54.7°). Note that θ=54.7° corresponds to the {111} plane.

As described above, in the method for manufacturing an epitaxial wafer according to the first embodiment, the bevel portion on the front surface side is obliquely polished to form the outer peripheral slope S before the epitaxial layer 103 is formed. This forms the epitaxial layer 103 not only on the growth surface G but also on the outer peripheral slope S. This makes it possible to suppress the occurrence of steps and stacking faults at the boundary between the epitaxial layer 103 and the growth region 104 on the suppression film 102. Therefore, the first embodiment makes it possible to provide a method for manufacturing an epitaxial wafer capable of improving the yield of semiconductor devices.

### Second Embodiment

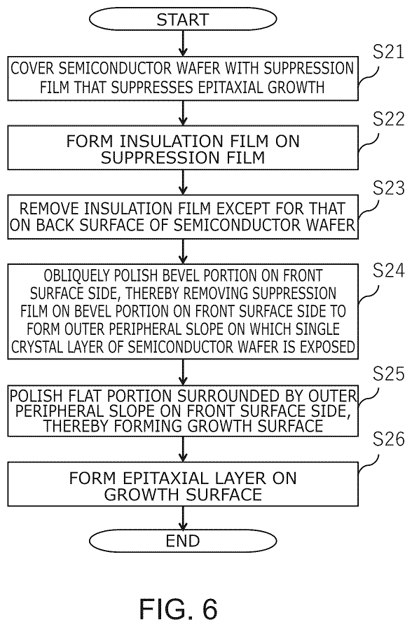

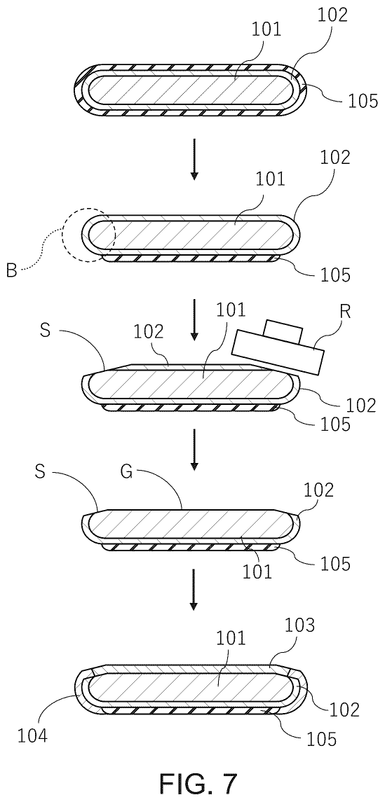

With reference to FIGS. 6 and 7, a method for manufacturing an epitaxial wafer according to this embodiment is described. FIG. 6 is a flowchart of a method for manufacturing an epitaxial wafer according to a second embodiment. FIG. 7 is a schematic view corresponding to FIG. 6, showing the manufacturing process of an epitaxial wafer according to the second embodiment. Note that in FIG. 7, step S21, which is described below, is the same as step S11 in the first embodiment, and therefore the portion relating to step S21 is not shown.

One of the differences between the second embodiment and the first embodiment is that the second embodiment includes a process of forming a Low Temperature Oxide (LTO) on the back surface of the semiconductor wafer. The second embodiment is described below, focusing on the differences.

Step S21: The semiconductor wafer 101 is covered with a suppression film 102 that suppresses epitaxial growth. This step is the same as step S11 described in the first embodiment, and detailed description is omitted.

Step S22: A protective film 105 is formed on the suppression film 102 formed in step S21. Specifically, the semiconductor wafer is subjected to a dry oxidation process or a wet oxidation process, thereby depositing a silicon oxide film. More specifically, this silicon oxide film is an LTO film.

Note that the protective film 105 is not limited to a silicon oxide film, and may be formed using silicon nitride (Si₃N₄), alumina (Al₂O₃), polyimide, or the like.

Step S23: the protective film 105 is removed except for that on the back surface of the semiconductor wafer 101. Specifically, wet etching is performed using a chemical liquid mainly containing hydrogen fluoride to selectively remove only the silicon oxide film except for that on the back surface of the semiconductor wafer 101, while leaving the suppression film 102.

The method for removing the protective film 105 is not limited to this, and the protective film 105 may be removed by, for example, dry etching.

Step S24: A bevel portion B on the front surface side of the semiconductor wafer 101 is polished obliquely to remove the suppression film 102 on the bevel portion B on the front surface side, thereby forming an outer peripheral slope S on which the single crystal layer of the semiconductor wafer 101 is exposed. Specifically, as shown in FIG. 7, a grindstone R is applied to the bevel portion B on the front surface side, and the semiconductor wafer 101 is rotated, thereby grinding the bevel portion B obliquely with respect to the horizontal plane.

Note that the magnitude of the facet angle θ that the outer peripheral slope S makes with the horizontal plane is as described in the first embodiment.

Step S25: The flat portion is polished that is surrounded by the outer peripheral slope S on the front surface side of the semiconductor wafer 101, thereby removing the suppression film 102 on the flat portion to form a growth surface G on which the single crystal layer is exposed. This step is similar to step S13 described in the first embodiment, and detailed description is omitted.

Step S26: An epitaxial layer 103 is formed on the growth surface G of the semiconductor wafer 101. In this step, a growth region 104 is formed by epitaxial growth processing on the suppression film 102 except for that on the front surface side. This step is similar to step S14 described in the first embodiment, and detailed description is omitted.

In the method for manufacturing an epitaxial wafer according to the second embodiment, as in the first embodiment, forming the outer peripheral slope S in advance makes it possible to suppress the occurrence of steps and stacking faults at the boundary between the epitaxial layer 103 and the growth region 104 on the suppression film 102. Therefore, the second embodiment makes it possible to provide a method for manufacturing an epitaxial wafer capable of improving the yield of semiconductor devices.

Furthermore, according to the second embodiment, a protective film 105 is formed on the back surface of the semiconductor wafer 101, thereby making it possible to suppress the out-diffusion of dopants from heavily doped substrate, for example.

In addition, the suppression film 102 in the first and second embodiments can be brought into direct contact with (can be directly deposited on) the back surface of the semiconductor wafer 101, thereby functioning as a gettering layer that physically protects the device surface of the epitaxial wafer from contamination caused by metal atoms and the like. When the suppression film 102 is made to play the role of a gettering layer, the protective film 105 may be formed after the suppression film 102 is formed on the semiconductor wafer 101. In this case, the protective film 105 and the suppression film 102 in the bevel portion are removed in the same manner as in the above embodiment, leaving the suppression film 102 in the bevel portion exposed.

According to at least one of the embodiments described above, the bevel portion on the front surface side is obliquely polished to form the outer peripheral slope before the epitaxial layer is formed, thereby making it possible to manufacture an epitaxial wafer capable of improving the yield of semiconductor devices.

In the above embodiment, the semiconductor wafer 101 is a silicon wafer. However, a semiconductor wafer other than a silicon wafer may be used as long as the bevel portion has a pointed shape through the formation of an epitaxial layer. For example, the semiconductor wafer 101 may be a wafer of silicon carbide (SiC), gallium nitride (GaN), diamond, or the like. When the semiconductor wafer 101 is a silicon carbide wafer, the first layer is a single crystal silicon carbide layer. When the semiconductor wafer 101 is a gallium nitride wafer, the first layer is a single crystal gallium nitride layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A method for manufacturing an epitaxial wafer, the method comprising:
covering a semiconductor wafer with a first film that suppresses epitaxial growth;
polishing a bevel portion on a front surface side of the semiconductor wafer, thereby removing the first film on the bevel portion on the front surface side to form an outer peripheral slope on which a first layer of the semiconductor wafer is exposed;
polishing a flat portion surrounded by the outer peripheral slope on the front surface side of the semiconductor wafer, thereby removing the first film on the flat portion to form a first surface on which the first layer of the semiconductor wafer is exposed; and
forming a second layer on the first surface.

2. The method for manufacturing an epitaxial wafer according to claim 1, wherein the first layer is a single crystal layer and the second layer is an epitaxial layer.

3. The method for manufacturing an epitaxial wafer according to claim 1, wherein an angle that the outer peripheral slope makes with a horizontal plane is within a range of 10° to 45°.

4. The method for manufacturing an epitaxial wafer according to claim 3, wherein an angle that the outer peripheral slope makes with a horizontal plane is within a range of 10° to 25.2°.

5. The method for manufacturing an epitaxial wafer according to claim 1, wherein an angle that the outer peripheral slope makes with a horizontal plane is within a range of 10° to 25.2°.

6. The method for manufacturing an epitaxial wafer according to claim 1, wherein the outer peripheral slope is a {311} plane, a {511} plane or a {811} plane.

7. The method for manufacturing an epitaxial wafer according to claim 1, wherein the semiconductor wafer is a silicon wafer.

8. The method for manufacturing an epitaxial wafer according to claim 7, wherein the first layer is a silicon single crystal layer.

9. The method for manufacturing an epitaxial wafer according to claim 7, wherein the first film is a polycrystalline silicon film.

10. The method for manufacturing an epitaxial wafer according to claim 7, wherein the first film is an amorphous silicon film.

11. The method for manufacturing an epitaxial wafer according to claim 1, wherein the semiconductor wafer is a silicon carbide wafer.

12. The method for manufacturing an epitaxial wafer according to claim 11, wherein the first layer is a single crystal silicon carbide layer.

13. The method for manufacturing an epitaxial wafer according to claim 1, wherein the semiconductor wafer is a gallium nitride wafer.

14. The method for manufacturing an epitaxial wafer according to claim 13, wherein the first layer is a single crystal gallium nitride layer.

15. The method for manufacturing an epitaxial wafer according to claim 1, further comprising:
after covering the semiconductor wafer with the first film and before forming the outer peripheral slope,
forming a protective film on the first film; and
removing the protective film except for the protective film on a back surface of the semiconductor wafer.

16. The method for manufacturing an epitaxial wafer according to claim 15, wherein a low-temperature oxide film is formed as the protective film.

17. The method for manufacturing an epitaxial wafer according to claim 15, wherein a silicon oxide film is formed as the protective film.

18. The method for manufacturing an epitaxial wafer according to claim 15, wherein a silicon nitride film is formed as the protective film.

19. The method for manufacturing an epitaxial wafer according to claim 15, wherein an aluminum oxide film is formed as the protective film.

20. The method for manufacturing an epitaxial wafer according to claim 15, wherein a polyimide film is formed as the protective film.
